(19) United States
(12) Patent Application Publication
(10) Pub. No.: US 2022/0224347 A1
(43) Pub. Date: Jul. 14, 2022

(54) CONTINUOUS-TIME PIPELINED ADCS WITH EVENT-DRIVEN SAMPLING

(71) Applicants: Analog Devices, Inc., Wilmington, MA (US); Massachusetts Institute of Technology, Cambridge, MA (US)

(72) Inventors: Gabriele MANGANARO, Winchester, MA (US); Rishabh MITTAL, East Walpole, MA (US); Hae-Seung LEE, Lexington, MA (US)

(73) Assignees: Analog Devices, Inc., Wilmington, MA (US); Massachusetts Institute of Technology, Cambridge, MA (US)

(21) Appl. No.: 17/571,485

(22) Filed: Jan. 8, 2022

Related U.S. Application Data
(60) Provisional application No. 63/136,634, filed on Jan. 12, 2021.

(51) Int. Cl. H03M 1/06; H03M 1/00

(52) U.S. Cl. CPC H03M 1/0626; H03M 1/002

(57) ABSTRACT

Uniformly-sampled, residue-generating analog-to-digital converters (ADCs), such as uniformly-sampled continuous-time pipelined ADCs, suffer from over-ranging of the residue signal, which can lead to severe signal distortion. Conventionally, power consuming techniques and oversampling are used to address the over-ranging problem. To reduce the range of the residue signal and reduce other impairments, an event-driven sub-quantizer (sub-ADC) and a sub-digital-to-analog converter (sub-DAC) can be implemented in at least one of the stages of the residue-generating ADC, to generate a continuous-time residue signal.

### PRIORITY APPLICATION

This is a non-provisional application claiming priority to and/or receive benefit from U.S. Provisional Application No. 63/136,634, filed on 12 Jan. 2021. The US Provisional Application is incorporated herein by reference in its entirety.

### TECHNICAL FIELD OF THE DISCLOSURE

The present disclosure relates to the field of integrated circuits, in particular to analog-to-digital converters (ADCs).

### BACKGROUND

In many electronics applications, an ADC converts an analog input signal to a digital output signal, e.g., for further digital signal processing or storage by digital electronics. Broadly speaking, ADCs can translate analog electrical signals representing real-world phenomenon, e.g., light, sound, temperature, electromagnetic waves, or pressure for data processing purposes. For instance, in measurement systems, a sensor makes measurements, and generates an analog signal. The analog signal would then be provided to an ADC as input to generate a digital output signal for further processing. In another instance, a transmitter generates an analog signal using electromagnetic waves to carry information in the air or a transmitter transmits an analog signal to carry information over a cable. The analog signal is then provided as input to an ADC at a receiver to generate a digital output signal, e.g., for further processing by digital electronics.

Due to their wide applicability in many applications, ADCs can be found in places such as broadband communication systems, audio systems, receiver systems, etc. Designing circuitry in ADC is a non-trivial task because each application may have different needs in performance, power, cost, and size. ADCs are used in a broad range of applications including Communications, Energy, Healthcare, Instrumentation and Measurement, Motor and Power Control, Industrial Automation, and Aerospace/Defense. As the number of applications needing ADCs grow, the need for fast, low power, and accurate conversion also grows.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 is an illustrative block diagram of a residue-generating ADC, according to some embodiments of the disclosure;

FIG. 2 is an illustrative block diagram of a first stage and a part of a second stage of a uniformly-sampled residue-generating ADC implemented with continuous-time circuitry, according to some embodiments of the disclosure;

FIG. 3 is an illustrative block diagram of a continuous-time, uniformly-sampled residue-generating ADC, according to some embodiments of the disclosure;

FIG. 4 illustrates operation of an event-driven, level-crossing ADC, according to some embodiments of the disclosure;

FIG. 5 is an illustrative block diagram of a residue-generating ADC having a continuous-time stage with event-driven, asynchronous circuitry, according to some embodiments of the disclosure;

FIG. 6 is a plot of a sinusoidal input signal, a signal representing a uniformly and synchronously sampled and quantized input signal, and a signal representing an event-driven, asynchronous quantized input signal, according to some embodiments of the disclosure;

FIG. 7 is a plot of a residue signal generated by a uniformly-sampled system, and a continuous-time residue signal generated by an event-driven, continuous-time system, according to some embodiments of the disclosure;

FIG. 8 is an illustrative block diagram of a continuous-time residue-generating stage with event-driven, asynchronous circuitry, according to some embodiments of the disclosure;

FIG. 9 is an illustrative circuit diagram of an event-driven, asynchronous comparator, and an event-driven, asynchronous digital-to-analog converter (DAC) cell, according to some embodiments of the disclosure; and

FIG. 10 is a flow diagram illustrating a method for preventing over-ranging of a residue signal in a residue-generating ADC, according to some embodiments of the disclosure.

### DETAILED DESCRIPTION

### Overview

Uniformly-sampled, residue-generating analog-to-digital converters (ADCs), such as uniformly-sampled continuous-time pipelined ADCs, suffer from over-ranging of the residue signal, which can lead to severe signal distortion. Conventionally, power consuming techniques and oversampling are used to address the over-ranging problem. To reduce the range of the residue signal and reduce other impairments, an event-driven sub-quantizer (sub-ADC) and a sub-digital-to-analog converter (sub-DAC) can be implemented in at least one of the stages of the residue-generating ADC, to generate a continuous-time residue signal.

How Residue-Generating ADCs Work

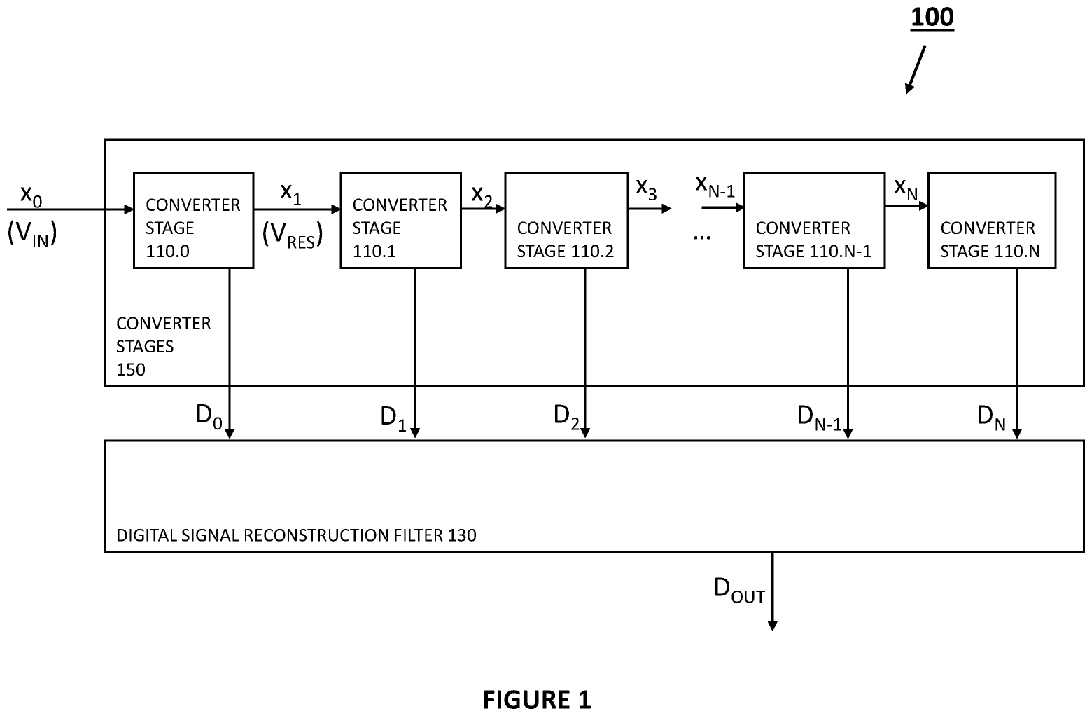

FIG. 1 is an illustrative block diagram of a residue-generating ADC 100, according to some embodiments of the disclosure. The residue-generating ADC 100 includes converter stages 150 and digital signal reconstruction filter 130. Residue-generating ADCs are sometimes referred to as pipelined ADCs.

The converter stages 150 includes a plurality of converter stages 110.0-110.N (or N+1 stages), connected in series, in pipeline, or in cascading configuration. Each converter stage (referred herein as a stage) may receive a respective analog input signal (“x₀”, “x₁”, “x₂”, “x₃” . . . “x_{N-1}”, and “x_{N}”), and may generate a respective analog output signal (“x₁”, “x₂”, “x₃” . . . “x_{N-1}”, and “x_{N}”) and a respective digital output signal (“D₀”, “D₁”, “D₂”, “D₃” . . . “D_{N-1}.”, and “D_{N}”). The respective analog output signals can be residues of the respective converter stages, formed by summation/subtraction of the analog input signal to the converter stage and an analog signal reconstructed from the digital output signal (e.g., x₁ is a residue signal of converter stage 110.0).

The converter stages 150 have respective bits of digital resolution (“N₀”, “N₁”, “N₂”, “N₃” . . . “N_{N-1}”, and “N_{N}”). The converter stages 150 can have the same number of bits of digital resolution, or the converter stages 150 can have different numbers of bits of digital resolution. Each converter stage may generate respective digital output signals, which may be combined to form an overall digital output signal D_{OUT} for the residue-generating ADC 100. The digital output signals (e.g., “D₀”, “D₁”, “D₂”, “D₃” . . . “D_{N-1}.”, and “D_{N}”) can be provided to a digital signal reconstruction filter 130, which combines and/or filters the respective digital output signals and form the final converter digital output signal D_{OUT} representing the analog input signal x₀.

For simplicity, some signal paths may not be shown. For instance, in some cases, one or more converter stages may receive other analog input signals (e.g., analog input signals of the previous stages and/or analog input signals of subsequent stages).

The stages of the residue-generating ADC 100 can be implemented with the same kind of converter architecture, or a combination of different converter architectures. Possible converter architectures (characterized by the type of quantizer used in the stage) include: DS modulation (e.g., as multi-stage noise shaping (MASH) ADCs), Flash conversion (e.g., as in pipelined ADCs), successive approximation register (SAR) conversion, and voltage-controlled-oscillator-based (VCO-based) conversion.

Residue-generating ADC 100 can be a continuous-time (CT) converter, which means that the converter stages 150 have CT circuitry, and do not use discrete-time (DT) circuitry for conversion, e.g., switched-capacitor circuits. CT circuitry can operate with lower power and achieve better wideband performance than its DT counterparts. CT circuitry can avoid issues traditionally associated with switched-capacitor circuits in DT ADCs. However, CT circuitry can be more difficult to design. In some cases, the residue-generating ADC 100 can be a hybrid CT-DT converter, where one or more stages of the converter stages 150 uses CT circuitry, and one or more stages of the converter stages 150 uses DT circuitry.

How Uniformly-Sampled CT Residue-Generating ADCs Work

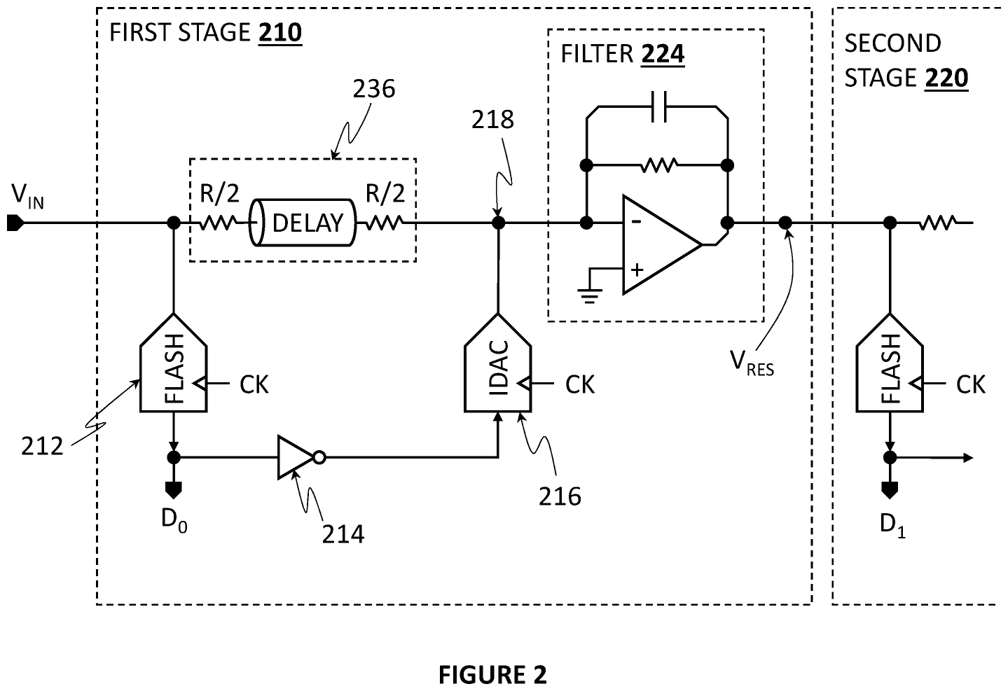

FIG. 2 is an illustrative block diagram of a first stage 210 and a part of a second stage 220 of a uniformly-sampled residue-generating ADC implemented with continuous-time circuitry, according to some embodiments of the disclosure. V_{IN} is the continuous-time (not sampled) continuous-value (not quantized) analog input signal to the first stage. V_{RES} is the first stage's analog output signal, i.e., the residue signal. D₀ is the first stage 210's N₀-bit digital output signal. V_{RES} is provided to the second stage that follows the first stage.

The first stage 210 resolves and outputs a digital output signal, i.e., N₀-bit D₀. D₀ can contribute to the most significant bits of final converter digital output signal D_{OUT}. D₀ can include redundant bits. D₀ can be generated by quantizing the input V_{IN} with a sub-ADC (or quantizer) 212, depicted in the FIGURE as a clocked flash ADC. While a flash ADC is commonly used, other clocked quantizers could be used as the sub-ADC. The sub-ADC 212 performs two functions: sampling and quantization. The sub-ADC 212 is clocked by a clock signal, CK, having a constant sampling frequency fₛ. Accordingly, the digital output signal, i.e., the quantized N₀-bit D₀, at the sub-ADC 212's output is uniformly-sampled in time. This digital output signal D₀ is sign-inverted by inverter 214 and converted into a uniformly-sampled, level-quantized, continuous analog output by sub-DAC (or DAC) 216, depicted as a clocked current-steering DAC (IDAC) in the figure. While an IDAC is commonly used as the sub-DAC 216, other DACs could also be used, such as, resistor string DACs, or switched-capacitor DACs. The sub-ADC 212 and sub-DAC 216 can be controlled by the same clock signal CK (or two slightly phase-shifted copies of the same) at sampling frequency fₛ.

A CT delay path 236 is provided to delay the analog input signal V_{IN}, such that the analog input signal experiences a matched or specified frequency response (including delay or phase) as the path involving the sub-ADC 212 and the sub-DAC 216. The CT delay path 236 can be implemented using one or more of: a delay line, resistor-capacitor lattice(s), and inductor-capacitor lattice(s). Termination resistance may also be provided as part of the CT delay path 236. At summing node 218, the inverted analog (reconstructed) representation of the first stage 210's quantized and sampled digital output signal D₀ of V_{IN} (e.g., a coarsely digitized V_{IN}) and V_{IN} are summed.

The first stage 210's analog output signal V_{RES}, can be obtained by (low-pass) filtering the sum of the inverted analog (reconstructed) representation of the first stage 210's quantized and sampled digital output signal D₀ of V_{IN} (e.g., a coarsely digitized V_{IN}) and V_{IN}. The signal at the summing node 218 is provided to a filter 224, such as low-pass filter, to generate the analog output signal V_{RES}. The filter 224 can provide amplification or gain as needed for the next stage as well. The analog output signal V_{RES} constitutes the first stage 210's residue signal. The residue signal V_{RES} represents a residual part of the input voltage V_{IN} which is to be subsequently quantized by the following stages of the pipelined ADC, such as the second stage 220, so that a finer quantization of V_{IN} can be obtained. V_{RES} is fed to the second stage 220, to resolve additional less significant bits of the final converter digital output signal D_{OUT}.

Without loss of generality, the second stage 220 could be implemented by a suitable quantizer. In this diagram, the residue V_{RES} is realized at the output of a (low-pass) filter 224, making use of a trans-impedance amplifier (TIA). This filter 224 can also work as an analog filter for the sub-DAC 216's output, to attenuate the higher-order images of the sub-DAC 216's output, which otherwise can directly add onto V_{RES}. While filter 224 is shown as a first order filter, to sufficiently suppress the DAC output images caused by the synchronous clocked operation, in practice, a higher-order filter, such as a second, or third order filter is often preferred or even required.

This figure may suggest that the input signal V_{IN} and the analog output signal V_{RES} are continuous in time. However, sub-ADC 212 and sub-DAC 216 of the first stage 210, are driven by clock CK. Therefore, the analog output signal V_{RES} is a uniformly-sampled, level-quantized, continuous signal, generated by a uniformly-sampled converter system.

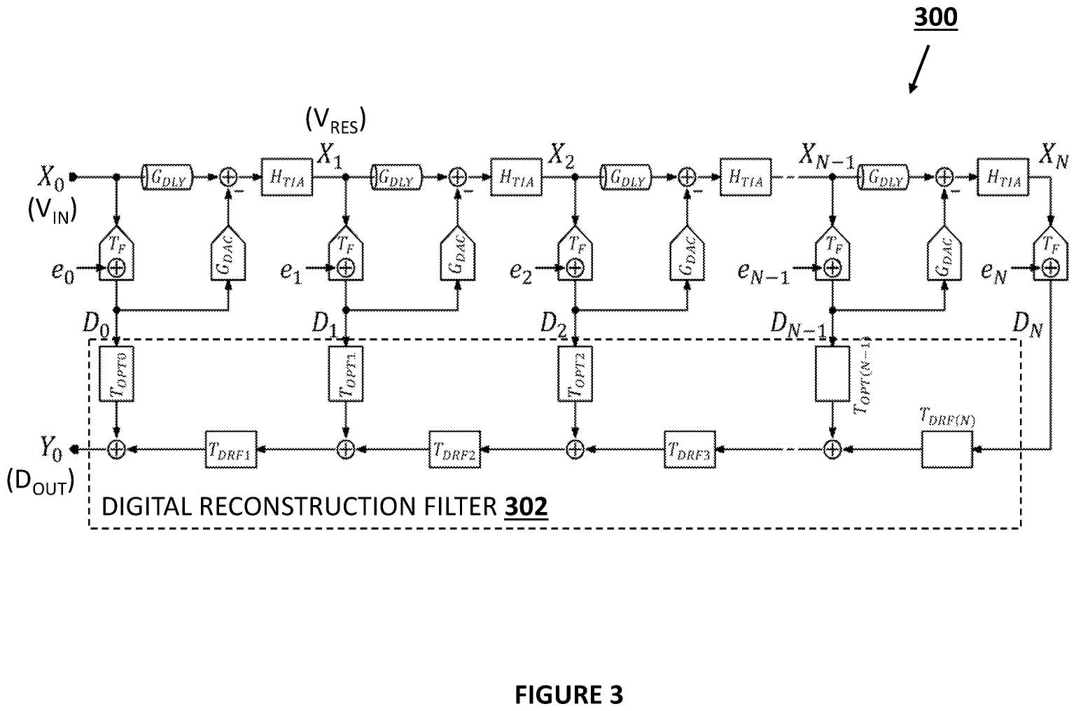

FIG. 3 is an illustrative block diagram of a continuous-time, uniformly-sampled residue-generating ADC 300, according to some embodiments of the disclosure. The example shown includes N+1 cascaded converter stages to digitize analog input signal Xo. It is understood that the converter stages can be implemented in a continuous-time, uniformly-sampled residue-generating ADC. The continuous-time, uniformly-sampled residue-generating ADC 300 also includes a digital reconstruction filter 302 (comprising sub-filters T_{OPT0}-T_{OPT(N-1)} and T_{DRF1}-T_{DRF(N)}) to combine all sub-ADC's digital output signals D₀-D_{N} to generate a final uniformly-sampled digital output signal Y₀.

Residue Over-Ranging in Uniformly-Sampled CT Residue-Generating ADCs

While the uniformly-sampled CT residue-generating ADCs have several strengths, they also suffers from some fundamental shortcomings.

The first issue is that, unlike discrete-time pipelined ADC where the output range of each stage is well-bounded by design, in uniformly-sampled continuous-time residue-generating ADCs, the residue signal V_{RES} is likely to over-range, especially when the input signal V_{IN} is of large amplitude and of higher frequency. If V_{RES} exceeds the input range of the next stage, then the next stage saturates, and severe distortion is introduced in the ADC digitized output Y₀. Depending on the implementation details and whether or not track-and-hold stages are being introduced or not in front of the pipelined stages, analogous over-ranging can also occur for the residue generation at the output of the subsequent stages. Referring back to FIG. 2, the reasons for the residue over-ranging are mainly due to:
Reason (1) mismatches between:
   the transfer function of the main V_{IN}-to-I signal path, i.e., the path from the input V_{IN} to the virtual ground of the filter 224 generating V_{RES}, and
   the transfer function of the signal path having the quantizer followed by the DAC of the stage, and
Reason (2) the DAC's output signal images.

Reason (2) is the primary problem causing residue over-ranging. In addition to reason (2), residue over-ranging can also occur as result of unsuppressed out-of-band signals.

Some mitigation techniques are available to address the impact or effect of residue over-ranging. None of the techniques eliminates the problem of residue over-ranging all together.

In one technique, careful design and calibration are used to address reason (1), but the mismatch problem is bounded only within a fraction of the first Nyquist range of the actual sample rate of the converter. As a result, the ADC operates as an oversampled ADC with a minimum practical over sampling ratio (OSR) of about 4. Over sampling is not ideal, since higher sampling rates consume more power.

In another technique, signal range is extended, or added by introducing redundancy in the stages. The extended signal range is usually reserved or dedicated to addressing other impairments such as comparator offsets. Providing for even more extended signal range can be an expensive design proposition.

In yet another technique, the filter's out-of-band suppression can be increased to address reason (2). However, use of a TIA in the filter would require that the analog input signal V_{IN}'s bandwidth to be substantially lower than fₛ/2, which can be a significant limitation on the input bandwidth of the ADC.

In yet a further technique, a combination of digital and mixed-signal multi-rate filtering and interpolation can be implemented to address reason (2). The technique alters or reduces the magnitude of the higher frequency lobes shaping the power levels of the DAC's images. The filtering and interpolation increase power consumption.

In all these techniques, power consumption is increased for the intended input signal bandwidth. Alternatively, either the input signal bandwidth needs to be limited or OSR is increased (with additional power consumption).

To Eliminate Residue Over-Ranging all Together, the ADC is Implemented with an Event-Driven, Asynchronous System

Rather than mitigating the impact of residue over-ranging, it is possible to design a continuous-time residue-generating ADC that avoids residue over-ranging entirely. It is not intuitive or trivial to design an ADC that avoids residue over-ranging. To eliminate residue over-ranging, it is important to examine closely the primary reasons for residue over-ranging. One primary reason, as discussed above and referring back to FIG. 2, are the DAC images that are created in the signal path having sub-ADC 212 and sub-DAC 216. The underlying reason that DAC images are created is the fact that the ADC has a uniformly-sampled system, which includes: the clock-driven sampling process that occurs in the sub-ADC 212, and the clock-driven switching that occurs in the sub-DAC 216.

To remove the underlying reason for residue over-ranging, one or more stages of a residue-generating ADC can be designed and implemented with an event-driven continuous-time system, comprising an event-driven, asynchronous sub-ADC, and an event-driven, asynchronous sub-DAC. Clock signals that are traditionally used to drive the sub-ADC and sub-DAC are eliminated. For the event-driven, asynchronous sub-ADC, this means that switched-capacitor circuits that are usually used to sample the analog input signal are absent. Additionally, clocked latches that are used to latch outputs of comparators are absent from the sub-ADC. For the event-driven, asynchronous sub-DAC, the clock-gated data paths are absent. Additionally, clocked driven transistors are absent. Events or changes in the data signals, not clock signals, drive the operations of asynchronous sub-ADC and asynchronous sub-DAC.

One way to implement an event-driven, asynchronous sub-ADC is to implement an ADC that is responsive to the analog input signal crossing one of a plurality of reference levels. In contrast, a uniformly-sampling ADC acquires and quantizes the analog input signal at a constant frequency fs, and is responsive to a clock signal. The output of a uniformly-sampling ADC would be a fixed-clock, discrete-time series of digital words. Moreover, a given digital word in the output is the closest quantized representation of the analog input signal at the time of sampling, which is determined solely by the sampling clock at frequency fs. Phrased differently, the process for generating the output of the uniformly-sampling ADC is not controlled by the analog input signal, but only by the clock signal.

For an event-driven, asynchronous, level-crossing sub-ADC, the output only changes when the analog input signal crosses one of the reference levels. Otherwise, the output remains the same. The reference levels represent the quantization set, and the output is a level-quantized representation of the analog input signal. Additionally, the output is a continuous-time output signal, having a variable data rate that is dependent on the activity, events, or level-crossings, of the analog input signal.

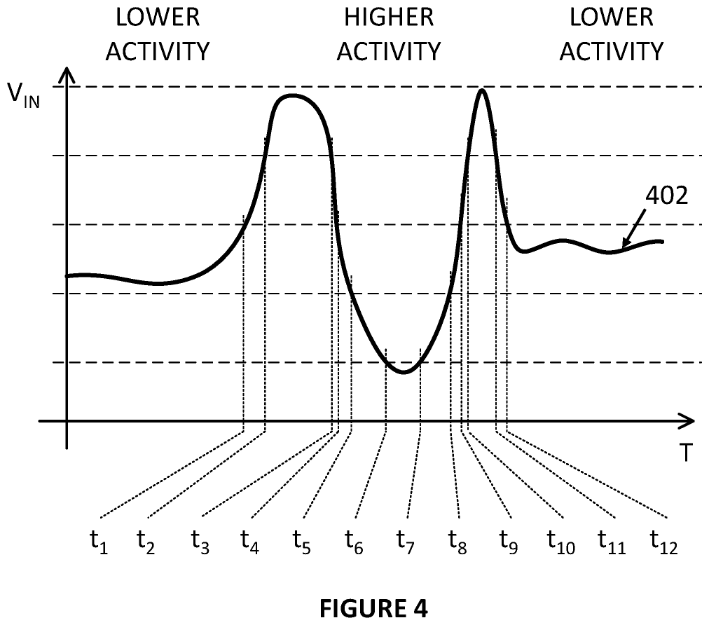

FIG. 4 illustrates operation of an event-driven, asynchronous, level-crossing ADC, according to some embodiments of the disclosure. Waveform 402 illustrates an exemplary analog input signal V_{IN} that varies in level, crossing a uniform set of reference levels, e.g., reference threshold voltages, marked by horizontal dashed lines. When V_{IN} crosses one of the quantization references levels, time of capture tₖ and a quantized voltage V_{IN}(tₖ) at the time of capture, e.g., {tₖ, V_{IN}(tₖ)}, are captured, and a corresponding digital output Dₖ is produced. To preserve the complete information and eventually process the signal, both the time of capture tₖ and the quantized voltage V_{IN}(tₖ) are accounted for. In contrast with the case of a uniformly-sampled ADC, the output of the event-driven ADC is asynchronous (meaning, opposite of being in synchrony or being triggered by a clock signal). Furthermore, the output can alternate between quiet periods of time when the input signal is relatively slow or even constant and few-to-no reference levels are crossed, such as before ti and after t₁₂, and bursts of high activity, such as between t₃ and is and between t₈ and t₁₂, when several new output codes are rapidly produced. In a way, the output data rate is adaptive, meaning the data rate changes with the input signal itself. In the case of sparse signals, such as those found in audio applications or in sensing applications (e.g., Internet of Things applications), the event-driven ADC can have the added benefit of reducing power consumption during the quiet periods.

In event-driven systems, the processing of quantized information does not progress synchronously, and does not get triggered by a uniform clock signal having a frequency of fs. Rather, processing steps are initiated, or triggered by asynchronous events such as level-crossing, as illustrated in FIG. 4. One advantage or property of such event-driven processing chain is that, while not immune to quantization errors, event-driven systems can be alias-free, as in, there are no signal aliases/images. Such advantage is particularly beneficial to addressing, even removing, the DAC images that can often cause residue over-ranging in a residue-generating ADC. Another advantage is that the event-driven, asynchronous sub-ADC and sub-DAC can be implemented using purely continuous-time circuitry (devoid of switched-capacitor circuits), which means that the resulting ADC can easily achieve wider bandwidth than its discrete-time counterparts.

Implementing Event-Driven, Asynchronous Circuitry in a Stage of a Residue-Generating ADC

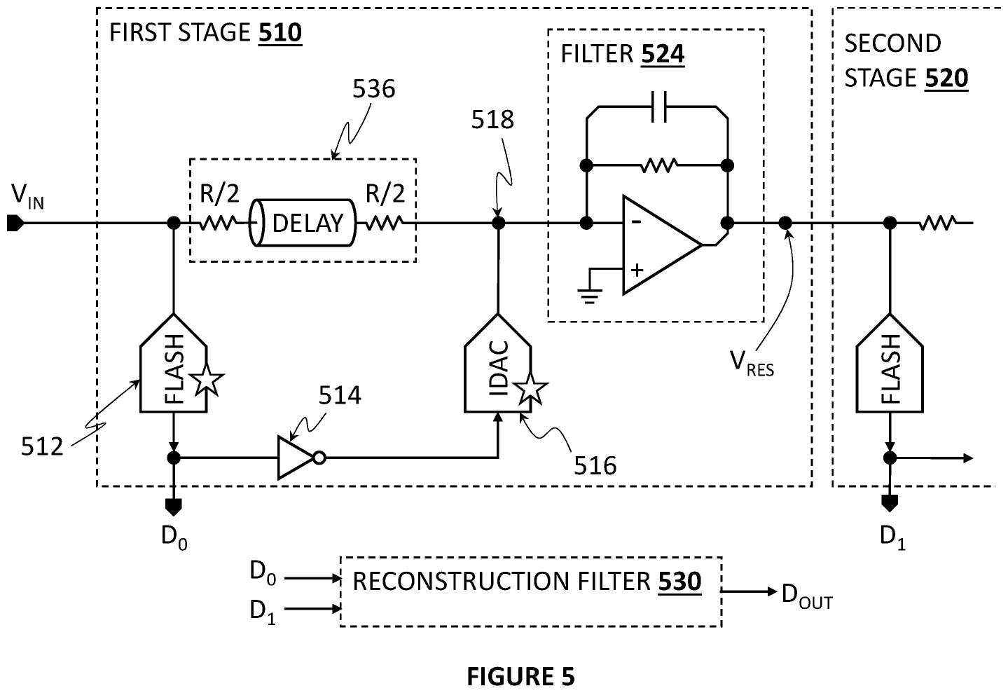

An event-driven continuous-time pipelined ADC with a significantly less risk of residue over-ranging can be implemented by replacing the sub-ADC and the sub-DAC of one or more stages of a continuous-time residue-generating ADC with an event-driven, asynchronous n sub-ADC and an event-driven, asynchronous sub-DAC respectively. By doing so, the clock signal CK is eliminated, and the stage can operate asynchronously. FIG. 5 is an illustrative block diagram of a residue-generating ADC having a continuous-time stage with event-driven, asynchronous circuitry, according to some embodiments of the disclosure. One key feature of the residue-generating ADC depicted in FIG. 5 is the absence of a clock signal (in contrast from the system shown in FIG. 2). Additionally, another key feature of the residue-generating ADC depicted in FIG. 5 is that the operation is directly driven by the continuous-time analog input signal V_{IN}. For purposes of discussion and illustration, the residue-generating ADC has at least a first stage 510 and a second stage 520, and the event-driven, asynchronous circuitry is implemented in the first stage 510. The residue-generating ADC can have more than two stages. The event-driven, asynchronous, continuous-time circuitry can be implemented in other stages besides the first stage 510. It is particularly effective at addressing residue over-ranging when the event-driven, asynchronous, continuous-time circuitry is implemented in at least the first stage 510.

The first stage 510 includes a delay circuit 536, a quantizer 512 (sub-ADC), an inverter 514, a DAC 516 (sub-DAC), and filter 524. The first stage 510 receives analog input signal V_{IN}, and generates an analog output signal, i.e., the continuous-time residue signal V_{RES}. The second stage 320 receives and quantizes the continuous-time residue signal V_{RES}. Level-quantized output D₀ of the first stage 510 and output D₁ of the second stage can be combined by reconstruction filter 530, which combines and/or filters the respective digital output signals from the stages, and forms the final converter digital output signal D_{OUT} representing the analog input signal V_{IN}.

The delay circuit 536 can delay an analog input signal V_{IN}. The delay circuit 536 is implemented with continuous-time circuitry. For proper residue generation, the delay circuit 536 delays the analog input signal by a same amount of latency of a (parallel) signal path having the quantizer 512 and the DAC 516. The signal path can be defined by the path taken by the analog input signal V_{IN} traversing through the quantizer 512 and the DAC 516 to reach node 518. Since there is inherent delay or latency in the signal path, the analog input signal V_{IN} is preferably delayed by the same amount when the analog input signal V_{IN} reaches node 518. Phrased differently, the delay circuit 536 may be designed to match the phase, and in some cases magnitude response of the signal path having the quantizer 512 and the DAC 516. Matching of the responses of the delay circuit 536 and the signal path having the quantizer 512 and the DAC 516 ensures that the subtraction of the reconstructed analog input signal from the DAC 516 is performed with a corresponding analog input signal V_{IN}.

In some embodiments, the delay circuit 536 may include termination resistance that provides termination matching of the transmission line carrying the analog input signal V_{IN}. In some cases, the circuit elements within the delay circuit 536 may be programmable. In some embodiments, the delay circuit 536 may include one or more resistor-capacitor lattices. In some embodiments, the delay circuit 536 may include one or more inductor-capacitor lattices. In some embodiments, the delay circuit 536 may include cascaded lattice circuits, such as two or more of: resistor-capacitor lattice(s) and inductor-capacitor lattice(s).

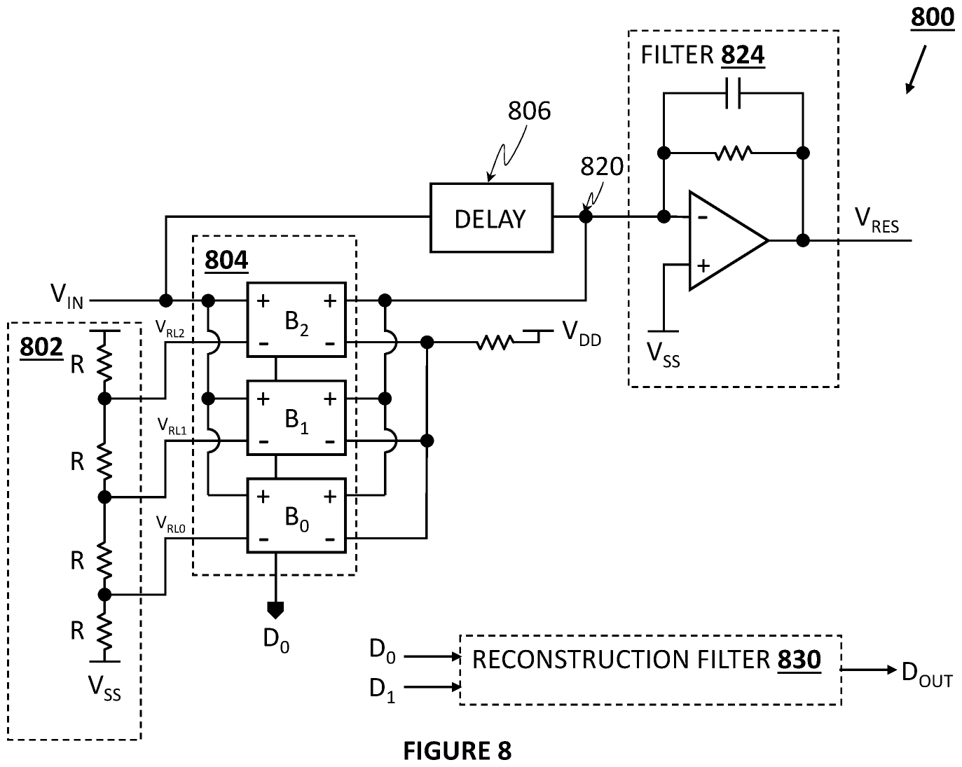

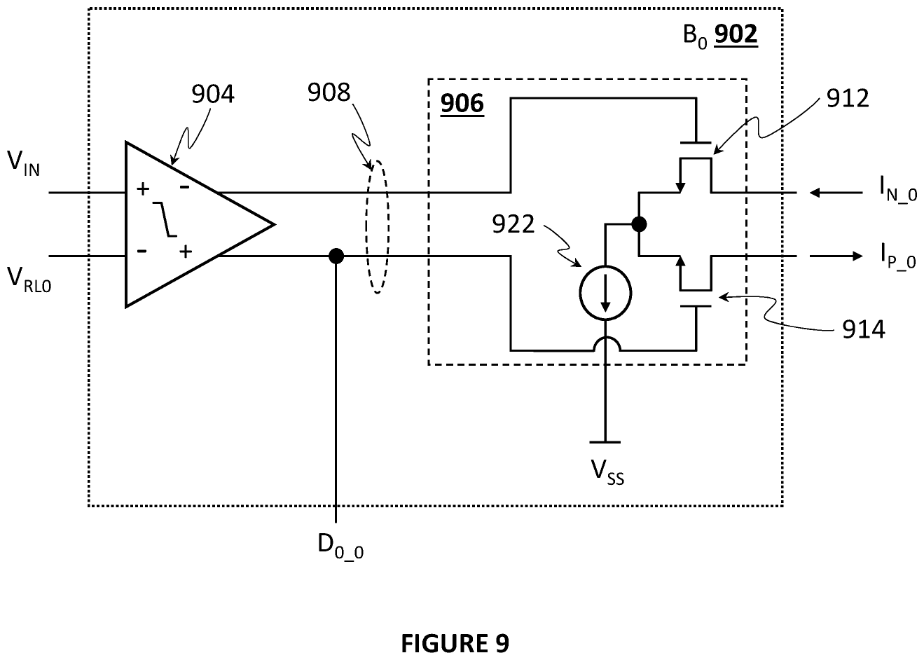

The quantizer 512 can change an output D₀ responsive to the continuous-time analog input signal V_{IN} crossing one of a plurality of reference levels. The quantizer 512 is clock-free, and is implemented using continuous-time circuitry. Exemplary details of the quantizer 512 are described in FIGS. 8-9. The operations of the quantizer 512 are event-driven, i.e., driven by continuous-time events in the analog input signal V_{IN} such as level-crossings, and not by a clock signal. The changes in the output D₀ are asynchronous, meaning the changes are not synchronous to a clock signal. Herein, the output D₀ of quantizer 512 is a continuous-time output signal, not a discrete-time output signal akin to the quantizer 212 of FIG. 2. In some cases, the output of the quantizer 512 changes aperiodically, meaning that the changes are not synchronous to transitions of a periodic clock signal. Rather the changes are triggered by events in the continuous-time analog input signal V_{IN}. Due to the event-driven, clock-free nature, the output rate of the quantizer 512, i.e., data rate of output D₀, is adaptive to (events and changes in) the analog input signal V_{IN}. The data rate becomes higher when there is more activity (events and changes) in the analog input signal V_{IN}, and the data rate becomes lower when there is less activity (events and changes) in the analog input signal V_{IN}.

The quantizer 512, being event-driven, is triggered by the analog input signal V_{IN} crossing one of the reference levels. Several factors may affect the operation and performance of the quantizer 512. One factor involves the number of reference levels being used. The number of reference levels affect the resolution of the quantizer 512. An event-driven quantizer 512 can extract higher resolution or more information from the analog input signal V_{IN} if more reference levels are used. Another factor involves the spacing of the reference levels across a range. The spacing of the reference levels can affect the sensitivity or responsiveness of the quantizer 512 to the analog input signal V_{IN} in a given range. The spacing of the reference levels can affect the output rate of the quantizer 512 (and, relatedly, power consumption of the quantizer 512) to the analog input signal V_{IN} in a given range, as well. The specific spacing of the reference levels for a given design, can depend on characteristics of the analog input signal V_{IN} and the desired operation and performance of the quantizer 512.

Referring back to FIG. 4, the reference levels can be uniformly spaced across a range. In some other embodiments, the reference levels are non-uniformly spaced across a range.

For instance, the analog input signal V_{IN} may be a sinusoidal signal oscillating between −V to +V. The reference levels for quantizer 512 may be more clustered or denser near zero, and more spaced out or less dense near the ends of the signal range (e.g., near −V and +V). Near zero, the sinusoidal signal changes quickly, and additional reference levels near zero may enable quantizer 512 to track the analog input signal V_{IN} better. Near zero, the output rate and power consumption of the quantizer 512 will be higher due to more level-crossings occurring within a given period of time.

In a different example, the analog input signal V_{IN} may exhibit peaks near an end of a signal range during some periods, and may have very little activity during some periods. Suppose the peaks embed relatively more useful information, whereas periods with very little activity may involve noise or relatively less interesting information. The reference levels for quantizer 512 may be more clustered or denser at an end of the signal range (locations of the peaks), and more spaced out, or less dense near zero. Near zero, less reference levels enables the quantizer 512 to remain in low power mode and not change states often. Near an end of the signal range, more reference levels enables the quantizer 512 to consume higher power and output more information about the signal activity of the peaks.

Referring back to FIG. 5, the DAC 516 is responsive to the continuous-time output of the quantizer 512. Note that continuous-time output of the quantizer 512 directly drives the DAC 516 without being gated by a clock signal, to provide fully asynchronous, and event-driven operation in first stage 510. The DAC 516 generates an analog, continuous-time, reconstructed version of analog input signal V_{IN} based on the continuous-time output D₀ of quantizer 512. Because quantizer 512 and DAC 516 are both continuous-time, and clock-free, the output of DAC 516 does not have DAC images.

Optionally, the output of quantizer 512 inverted by inverter 514. An explicit inverter is not required. For instance, differential signal paths may be swapped to implement inversion, or polarity of circuitry of quantizer 512 or circuitry of DAC 516 may be inverted to implement inversion. For illustration, DAC 516 is a current-mode DAC with current-steering DAC cells, but other types of DACs are envisioned by the disclosure.

By means of inverter 514, the reconstructed version of analog input signal V_{IN} from the output of DAC 516 is inverted and thus represents a negative or inverted analog reconstructed version of analog input signal V_{IN}. The inverted analog reconstructed version of analog input signal V_{IN} can be summed with the corresponding, delayed analog input signal at node 518 to carry out subtraction. Node 518 can generate a summed signal based on a delayed analog input signal from the delay circuit 536 and an output of the DAC 516. Because the delayed analog input signal from the delay circuit 536 is generated by continuous-time circuitry, and the output of DAC 516 does not have DAC images, the signal at node 518 also does not have DAC images.

The first stage 510's analog output signal V_{RES} can be obtained by filtering the signal at node 518. The signal at the summing node 518 is provided to a filter 524, to filter the summed signal at node 518 and generate the analog output signal V_{RES}. The filter 524 can provide amplification or gain as needed for the next stage. Note that the filter 524 no longer has the requirement to reject DAC images (in comparison to filter 224 of FIG. 2, which is typically implemented as a low-pass filter, and more often than not, is at least a second or third order filter), because the signal at the summing node 518 is alias-free. Accordingly, filter 524 may be designed to focus on limiting the bandwidth of the residue signal and suppress undesirable out-of-band signal content. Design requirements of filter 524 can be relaxed significantly. In some cases, a first order filter, as shown in FIG. 5 would be suitable. Using a first order filter as filter 524 advantageously saves power, area, and has less noise, when compared to a higher-order filter. Filter 524 can be implemented using other circuit architectures besides the one shown in FIG. 5. The analog output signal V_{RES} constitutes the first stage 510's residue signal. The residue signal V_{RES} represents a residual part of the input voltage V_{IN} which is to be subsequently quantized by the following stages of the residue-generating ADC, such as the second stage 520, so that a finer quantization of V_{IN} can be obtained. V_{RES} is fed to the second stage 520, to resolve additional lower significant bits of the final converter digital output signal D_{OUT}.

Without loss of generality, the second stage 520 could be implemented by a suitable quantizer. The second stage 520 could have the same architecture as first stage 510, although it is not necessary in all applications.

How Residue Over-Ranging is Prevented or Eliminated

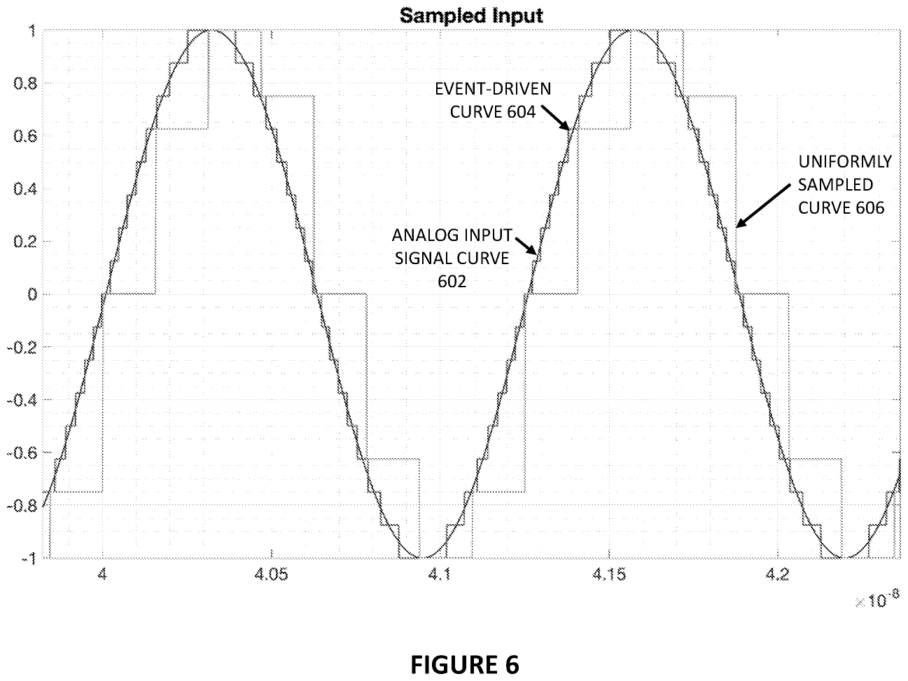

The impact of removing clocked circuitry, as illustrated by the first stage 510 of FIG. 5 is rather profound. FIG. 6 is a plot of a sinusoidal input signal, a signal representing a uniformly and synchronously sampled and quantized input signal, and a signal representing an event-driven, asynchronous quantized input signal, according to some embodiments of the disclosure. For example, suppose the analog input signal V_{IN} is a sinusoidal signal, represented by the curve 602 in FIG. 6. For simplicity sake but without loss of generality, that there are no processing delays or latency in the signal path having quantizer and DAC shown in FIGS. 2 and 5. In other words, V_{IN} is instantaneously sampled, and quantized by the quantizer 212. The quantizer 212's digital output is then instantaneously converted into an analog DAC output by DAC 216, which is represented by the curve 606 in FIG. 6. In the frequency domain, the latter has signal images in each and every Nyquist band and the images' power is shaped by the sync function determined by the sample rate fₛ. The signal images, as discussed in the previous sections, is one of the main reason for residue over-ranging. On the other hand, when using the event-driven, clock-free, continuous-time signal chain illustrated in FIG. 5, then the asynchronous DAC 516 output is represented by curve 604 of FIG. 6. For both curves 604 and 606, a 4-bit quantizer has been used to illustrate the differences and highlight the effect of using asynchronous circuitry as opposed to synchronous circuitry. Note that while curve 604 is quantized (in amplitude), its frequency spectrum is alias-free. Despite both the uniformly-sampled system and event-driven, clock-free system having the very same number of quantization levels (4-bits), the curve 604 more closely tracks/represents the original analog signal V_{IN} in comparison to the curve 606. The uniformly-sampled system is intrinsically coarser because the information is uniformly quantized both in voltage level and time. Conversely, the curve 604 as a result of an event-driven, clock-free system is uniformly quantized in voltage, but asynchronous in time, therefore, curve 604 can more closely track the original V_{IN} in time. In turn, the curve 604 also results into far more transitions than the curve 606. This means that the asynchronous, event-driven system illustrated by FIG. 5, can result into a higher digital word rate for output D₀ than the uniformly-sampled data output D₀ of the uniformly-sampled system illustrated by FIG. 2. It is worth noting that the data rate of the output D₀ of the asynchronous, event-driven system will be far lower in the case, in which, while keeping the same amplitude, V_{IN}'s frequency is much smaller than fₛ. In such case, the curve 606 of a uniformly-sampled system will produce several more codes for a given time than the curve 604 of an asynchronous, event-driven system. The reason is that a slowly varying waveform will cross the reference levels of an asynchronous, event-driven system much less frequently than a uniformly-sampled system. Hence the asynchronous, event-driven system would generate far fewer output codes for a given time interval than its uniformly-sampled counterpart. The uniformly-sampled counterpart would continue producing several uniformly spaced sequences of identical outputs until the input V_{IN} finally crosses another quantization level, and will continue producing several more identical digital outputs representing the new code, and so on.

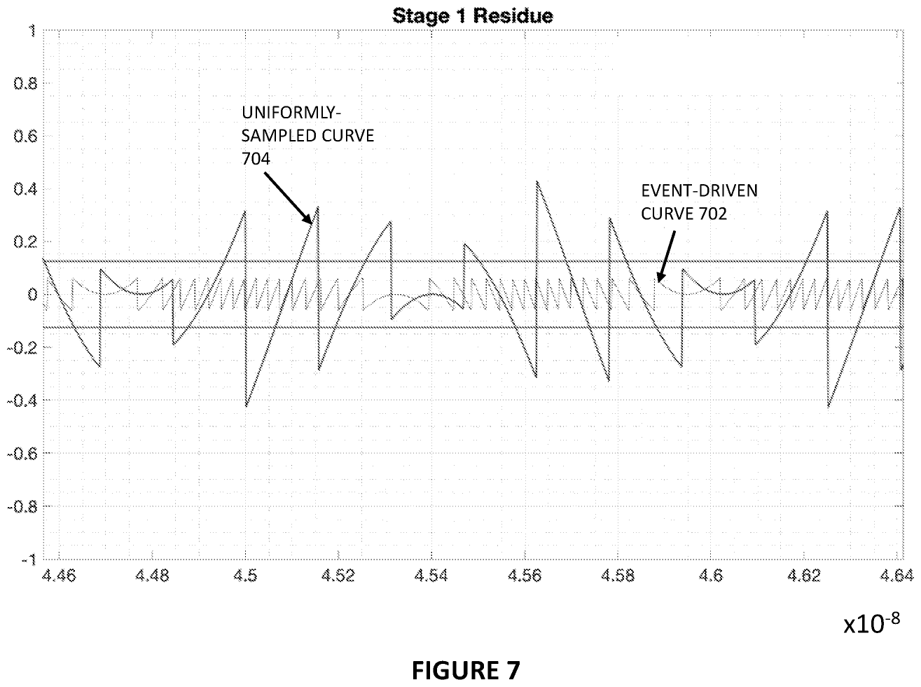

FIG. 7 is a plot of a residue signal generated by a uniformly-sampled system, and a residue signal generated by an event-driven, continuous-time system, according to some embodiments of the disclosure. The differences between the uniformly-sampled system and the event-driven are staggering. In the case of the uniformly-sampled system (e.g., such as the one illustrated in FIG. 2), the residue represented by curve 704 has wide amplitude. In the case of the event-driven, asynchronous, continuous-time system (e.g., such as the one illustrated in FIG. 5), the residue represented by curve 702 has substantially smaller amplitude. However, as already noted, in this case, the curve 702 resulting from the event-driven, asynchronous, continuous-time system has a higher frequency component than the curve 704 resulting from the uniformly-sampled system. As discussed previously, this frequency difference would reverse for inputs where the frequency is much smaller than fₛ. Note that, regardless of the input frequency, the amplitude of the residue V_{RES} for the asynchronous, event-driven system will always be either smaller or, in the extreme case, equal to the amplitude of the residue V_{RES} for the uniformly-sampled system. In the case of the uniformly-sampled system, the continuous-time analog input signal V_{IN} can cross different quantization levels before being sampled again, so the residue V_{RES} can easily grow to multiple least significant bits (LSBs), or even to full-scale in an extreme case, before a new sample is taken. In the case the case for the asynchronous, event-driven system, a new quantization is performed as soon as a different reference level is crossed, therefore keeping the amplitude the residue V_{RES} strictly bound within 1 LSB in all cases.

Exemplary Circuit Implementations for a Continuous-Time, Event-Driven, Asynchronous Stage in a Residue-Generating ADC

FIG. 8 is an illustrative block diagram of a continuous-time residue-generating stage with event-driven, asynchronous circuitry, according to some embodiments of the disclosure. The residue-generating stage 800 can be one of a plurality of stages of a residue-generating ADC, receiving a continuous-time analog input signal V_{IN}. The residue-generating stage 800 can be a first residue-generating stage that generates a continuous-time residue signal V_{RES}, which is then processed, or quantized by a second stage of the residue-generating ADC. The first residue-generating stage includes: a first continuous-time delay circuit 806, a first feedforward path 804, a first reference generator 802, a first summing node 820, and a first filter 824.

The first continuous-time delay circuit 806 shares same or similar functionality and structure as previously-described delay circuit 536. The first continuous-time delay circuit 806 receives the analog input signal V_{IN} at its input and generates a delayed analog input signal at its output. The first continuous-time delay circuit 806 can include termination resistance. The first continuous-time delay circuit 806 can include one or more resistors. The first continuous-time delay circuit 806 can include one or more transmission lines. The first continuous-time delay circuit 806 can include one or more resistor-capacitor lattices (in cascade if more than one is included). The first continuous-time delay circuit 806 can include one or more inductor-capacitor lattices (in cascade than one is included). The first continuous-time delay circuit 806 can include any one or more combination of such continuous-time delay elements. Using a combination of such continuous-time delay elements allow for a modular approach to designing a desired frequency response of the first continuous-time delay circuit 806. For instance, cascading different continuous-time delay elements can provide an aggregate frequency response across a wider bandwidth, which can be particularly suitable for wide bandwidth applications. Using a combination of such continuous-time delay elements can also provide better or closer frequency response matching between the first continuous-time delay circuit 806 and the first feedforward path 804.

The first feedforward path 804 includes continuous-time, asynchronous, event-driven circuitry that implements a first continuous-time quantizer and a first continuous-time DAC. The circuitry shares same or similar functionality and structure as previously-described quantizer 512 and DAC 516 (and inverter 514). The circuitry is shown as blocks B₀, B₁, and B₂ for illustration, implementing a 1.5-bit stage. The first continuous-time quantizer can be implemented as a flash ADC having a plurality of comparators. The first continuous-time quantizer can be implemented as a current-steering DAC having a plurality of DAC cells. A block can include circuitry that includes a comparator and a DAC cell. Details within a given block is shown in greater detail in FIG. 9. It is envisioned that a different number of blocks can be implemented to provide different resolution for the stage.

The first continuous-time quantizer receives the analog input signal V_{IN} at its input and generates a continuous-time output signal D₀ at its output. Same as quantizer 512, the first continuous-time quantizer is not clocked, and is event-driven. In other words, the first continuous-time quantizer is not triggered by any clock signals. An exemplary circuit implementation is illustrated in FIG. 9.

The first continuous-time quantizer is responsive to events of the analog input signal V_{IN}, involving the analog input signal V_{IN} crossing one of the reference levels. Accordingly, the first continuous-time quantizer receives a plurality of reference levels (e.g., in the form of reference voltages spread across a signal range), and the first reference generator 802 generates reference levels, e.g., V_{RL0}, V_{RL1}, and V_{RL2}, for the first continuous-time quantizer. One example of a first reference generator 802 is a resistor-ladder that can generate a plurality of different voltages across a range. Other implementations are possible, including implementations that allow for the reference levels to be shuffled or rotated, and implementations that allow for the reference levels to be programmable. As discussed previously, the number of reference levels and spacing of the reference levels have implications on the operation and performance of the first continuous-time quantizer. In some cases, the reference levels are uniformly spaced across a range. In some cases, the reference levels are non-uniformly spaced across a range. In some cases, the reference levels are closer to each other near a center of a range (e.g., zero volts) than ends of the range. In some cases, the reference levels are closer to each other at the end(s) of a range than near a center of a range (e.g., zero volts).

The first continuous-time DAC receives the continuous-time output signal D₀ at its input and generates a continuous-time reconstructed version of the analog input signal V_{IN} based on the continuous-time output signal D₀, which is a quantized version of the analog input signal V_{IN}. Same as the DAC 516, the first continuous-time DAC is not clocked, and is responsive to (events of) the continuous-time output signal D₀. In other words, the first continuous-time DAC is not triggered by any clock signals, and data paths are not gated by clock signals. An exemplary circuit implementation is illustrated in FIG. 9.

The first summing node 820 shares same or similar functionality and structure as summing node 518. The first summing node 820 receives the delayed analog input signal from the first continuous-time delay circuit 806, and a continuous-time output (the reconstructed version of the analog input signal V_{IN} based on the continuous-time output signal D₀) from the first continuous-time DAC. The first summing node 820 generates a continuous-time summed signal. While it is illustrated that the first summing node 820 performs current-mode summation, it is also possible, in some implementations that the functionality of summing/subtraction is done with voltage-mode summation.

The first filter 824 filters the continuous-time summed signal from the first summing node 820. The first filter 824 generates a continuous-time residue signal V_{RES}. The first filter 824 shares same or similar functionality and structure as filter 524. The first filter 824 is preferably implemented using continuous-time circuitry, and is not clocked by any clock signals. In some embodiments, the first filter 824 comprises an amplifier to amplify the continuous-time summed signal. In some cases, the amplifier include one or more closed-loop amplifiers. In some cases, the amplifier can include one or more open-loop amplifiers. In some cases, the amplifier is a trans-impedance amplifier to convert the (summed) current at the first summing node 820 to a voltage representing the continuous-time residue signal V_{RES}.

Though not shown in FIG. 8, the residue-generating ADC can include a second stage to quantize the continuous-time residue signal. In some embodiments, the second stage is another residue-generating stage, which can include a second continuous-time delay circuit, a feedforward path (having a second continuous-time quantizer and a second continuous-time DAC), a second summing node, and a second filter. It is not necessary that the second stage is also implemented with continuous-time, asynchronous, event-driven circuitry, but the second stage can be implemented in a similar manner as residue-generating stage 800. In some cases, the second stage is a final/last stage of a continuous-time residue-generating ADC (not generating any residue signal and resolves the least significant bits), where the second stage includes a second continuous-time quantizer, generating a second continuous-time output D₁. Any suitable continuous-time quantizer can be implemented. In some cases, the second stage includes a second discrete-time quantizer, or a hybrid continuous-time/discrete-time quantizer.

Additionally, the residue-generating can further include a reconstruction filter 830 (sharing same or similar functionality and structure as reconstruction filter 530) to receive the continuous-time output signal from the first residue-generating stage and a further output signal from the second stage, and generate a final output of the residue-generating ADC. In some embodiments, the reconstruction filter 830 comprises asynchronous logic, and is driven by (events of) the continuous-time output signals from the stages, such as continuous-time output signal D₀. In some embodiments, the reconstruction filter 830 comprises synchronous logic and samples the continuous-time output signals from the stages, such as continuous-time output signal D₀ synchronously with a clock signal.

As discussed above, the first feedforward path 804 can include a plurality of blocks B₀, B₁, and B₂. A block can include circuitry that includes an event-driven, asynchronous, continuous-time, clock-free comparator, and an event-driven, asynchronous, continuous-time, clock-free DAC cell coupled to the output of the comparator. The circuitry is responsive to a respective reference level (e.g., V_{RL0}, V_{RL1}, or V_{RL2}), and the output if the circuitry is responsive to the analog input signal V_{IN} crossing the reference level. FIG. 9 is an illustrative circuit diagram of an event-driven, asynchronous comparator 904, and an event-driven, asynchronous DAC cell 906, according to some embodiments of the disclosure. An exemplary block B₀ 902 is shown with illustrative continuous-time circuitry that implements the event-driven, asynchronous comparator 904, and an event-driven, asynchronous DAC cell 906. The implementation can be used for implementing blocks B₀, B₁, and B₂ of FIG. 8.

The comparator 904 is one of N comparators (N being a number of reference levels for the implementation) that make up the continuous-time quantizer of a residue-generating stage (e.g., quantizer 512). The comparators are responsive to N respective reference levels (e.g., V_{RL0}, V_{RL1}, and V_{RL2}). Together, the comparators generate parts for the continuous-time output D₀. The comparator 904 changes its output D_{0_0} when the analog input signal V_{IN} crosses the reference level V_{RL0}. For instance, the comparator 904 can continuously output a logic “0” when the analog input signal V_{IN} is below the reference level V_{RL0}, and comparator 904 can change its output to a logic “1” when the analog input signal V_{IN} crosses and becomes greater than the reference level V_{RL0}. The comparator 904 is not clocked, and its output changes in response to the event of the analog input signal V_{IN} crosses the reference level V_{RL0}. Such a comparator 904, being clock-free, operates at all times, and thus can consume more power than its clocked counterparts. Various types of continuous-time comparators can be implemented, such as an open-loop comparator (without feedback) or a regenerative comparator (with positive feedback). The circuitry for implementing comparator 904 would be absent of any clocked switched-capacitor circuits that samples the analog input signal V_{IN} or clocking that latches different phases of the comparator. In the example shown, comparator 904 generates a differential output 908.

The DAC cell 906 is one of N DAC cells that make up the continuous-time DAC of a residue-generating stage (e.g., DAC 516). The DAC cells are responsive to the respective continuous-time outputs of the comparators. In the example shown, DAC cell 906 is responsive to the differential output 908 of comparator 904. The DAC cell 906 changes its output (e.g., differential current output I_{N_0} and I_{P_0} when the continuous-time output of comparator 904 changes. The DAC cell 906 is not clocked by clock signals, and data paths or inputs to the DAC cell 906 are not gated by clock signals. In some embodiments, DAC cell 906 can be a current-mode DAC cell driven by the differential output 908 of the comparator 904. Referring back to FIG. 5, the DAC 516 can include current-mode DAC cells which are driven by respective outputs of the quantizer 512. Referring back to FIG. 9, DAC cell 906 has a differential pair of transistors, i.e., transistor 912 and transistor 914. The sources of the differential pair of transistors are connected to a current source 922. Accordingly, the differential output 908 of comparator 904 controls the gates of the differential pair of transistors to steer a current from current source 922 towards one of the differential output I_{N_0} and I_{P_0}.

Advantageously, the circuit implementations illustrated in FIG. 9 has benefits associated with continuous-time circuits. For instance, the comparator 904 may have wider bandwidth and faster speed than its discrete-time counterparts. Additionally, the lack of clock-gated data paths for the DAC cell 906 means that power-hungry clock drivers are omitted. Accordingly, power consumption, and complexity of the circuitry can be significantly reduced. The circuit implementations are meant to be illustrative of an event-driven, asynchronous, clock-free system, and are not intended to be limiting to the present disclosure.

While an explicit inverter is not shown, it is understood that the inversion operation can be embedded in comparator 904 and DAC cell 906 by ensuring that polarity is inverted by design.

Method for Preventing Over-Ranging

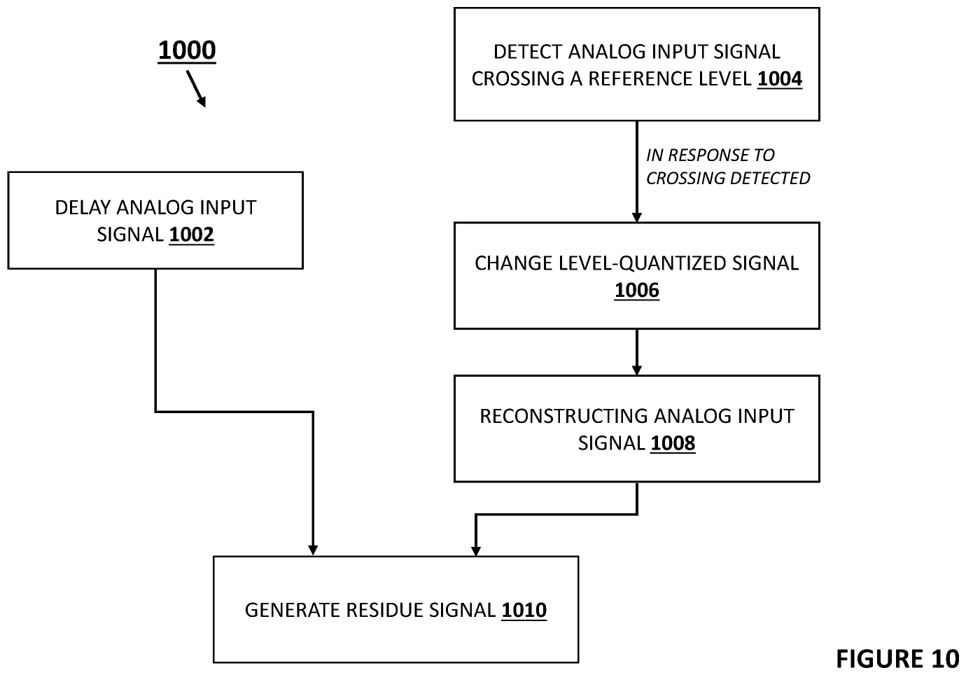

FIG. 10 is a flow diagram illustrating a method for preventing over-ranging of a residue signal in a residue-generating ADC, according to some embodiments of the disclosure. In 1002, a continuous-time delay circuit (e.g. delay circuit 536 or delay circuit 806) can delay an analog input signal. In 1004, a continuous-time, event-driven quantizer (e.g., quantizer 512) can detect the analog input signal (e.g., V_{IN}) crossing one of a plurality of reference levels. In 1006, in response to detecting the crossing, the continuous-time, event-driven quantizer can change a level-quantized signal (e.g., the continuous-time output of quantizer 512). In 1008, a continuous-time, asynchronous DAC (e.g., DAC 516) can reconstruct the analog input signal based on the level-quantized signal. In 1010, a summing node (e.g., node 518 or node 820) and a filter (e.g., filter 524 and 824) generates the continuous-time residue signal based on a delayed analog input signal from the continuous-time delay circuit and a reconstructed analog input signal from the continuous-time, asynchronous DAC. In some cases, the filter amplifies the continuous-time residue signal. The (amplified) continuous-time residue signal can be quantized by further circuitry (e.g., a second stage in the residue-generating ADC).

Advantageously, in 1006, changing the level-quantized signal can include changing the level-quantized signal-independent of a clock signal.

Advantageously, in 1008, reconstructing the analog input signal can include: reconstructing the analog input signal-independent of a clock signal.

In some embodiments, an asynchronous, clock-free logic is implemented as a reconstruction filter (e.g., one embodiment of reconstruction filter 530), where the asynchronous, clock-free logic asynchronously filters the level-quantized signal from the continuous-time, event-driven quantizer. In some embodiments, clocked sampling may only occur at the end of the signal chain, where clocked sampling is only performed on a continuous-time output (D_{OUT}) of the residue-generating ADC.

Design of the Delay Circuit in an Asynchronous Clock-Free Residue-Generating Stage

Several considerations can be taken into account when providing the continuous-time, event-driven, asynchronous feedforward path and continuous-time delay circuit as seen in FIGS. 5, and 8-9. In a clocked continuous-time stage of a residue-generating ADC, the latency of the feedforward path is a direct function or multiple of the clock period by virtue of the clocked operations. For instance, the feedforward path often has fixed latency of 1.5 clock periods. When the feedforward path is clock-free, latency is no longer dependent of a clock. Therefore, a designer may design the circuitry for the feedforward path in a manner to ensure the latency is constant and substantially signal-independent. Likewise, the delay circuit is implemented to match the latency of the feedforward path. Comparators of the quantizer can be differential and have very high gain. While there is a delay for a comparator to change state, this delay is generally very short, is fixed, and is signal-independent. Generally speaking, the circuit implementation illustrated in FIG. 9 beneficially enables very fast operation when compared against a typical clocked stage of a residue-generating ADC, which often has a sequence of sensing and latching steps leading to a latency of a few clock cycles. The circuit implementation illustrated in FIG. 9 having shorter latency means that the accompanying delay line is less bulky, easier to design, and its delay can hold well over a wider bandwidth.

In practice, this constant delay that is signal-independent may only hold true to a point or limit for a given design. For instance, the delay may be somewhat input signal-independent, since latency will be greater when the analog input signal is close to the reference level (or threshold). Such an issue can be mitigated by biasing the comparator front end with a higher quiescent current. As a result, the comparator can be designed and implemented to make the latency substantially constant and signal-independent.

### Examples

Example 1 is a residue-generating analog-to-digital converter (ADC), comprising: (1) a first residue-generating stage, comprising: a first continuous-time delay circuit to receive an analog input signal and generate a delayed analog input signal; a first continuous-time quantizer to receive the analog input signal and generate a continuous-time output signal; a first continuous-time digital-to-analog converter (DAC) responsive to the continuous-time output signal; a first summing node to receive the delayed analog input signal and an output from the first continuous-time DAC and generate a continuous-time summed signal; and a first filter to filter the continuous-time summed signal, and generate a continuous-time residue signal; and (2) a second stage to quantize the continuous-time residue signal.

In Example 2, the residue-generating ADC of Example 1 can optionally include comprising: a reconstruction filter to receive the continuous-time output signal from the first residue-generating stage and a further output signal from the second stage, and generate a final output of the residue-generating ADC.

In Example 3, the residue-generating ADC of Example 2 can optionally include the reconstruction filter comprising asynchronous logic.

In Example 4, the residue-generating ADC of any one of Examples 1-3, can optionally include the second stage comprising a second continuous-time delay circuit, a second continuous-time quantizer, a second continuous-time DAC, a second summing node, and a second filter.

In Example 5, the residue-generating ADC of any one of Examples 1-4 can optionally include the second stage comprising a second continuous-time quantizer.

In Example 6, the residue-generating ADC of any one of Examples 1-5 can optionally include the first continuous-time delay circuit comprising a resistor.

In Example 7, the residue-generating ADC of any one of Examples 1-6 can optionally include the first continuous-time delay circuit comprising a transmission line.

In Example 8, the residue-generating ADC of any one of Examples 1-7 can optionally include the first continuous-time delay circuit comprising a resistor-capacitor lattice.

In Example 9, the residue-generating ADC of any one of Examples 1-8 can optionally include the first continuous-time delay circuit comprising an inductor-capacitor lattice.

In Example 10, the residue-generating ADC of any one of Examples 1-9 can optionally include the first continuous-time quantizer not being triggered by any clock signals.

In Example 11, the residue-generating ADC of any one of Examples 1-10 can optionally include the first residue-generating stage further comprising a first reference generator.

In Example 12, the residue-generating ADC of Example 11 can optionally include the first reference generator generating reference levels for the first continuous-time quantizer.

In Example 13, the residue-generating ADC of Example 12 can optionally include the reference levels being uniformly spaced across a range.

In Example 14, the residue-generating ADC of Example 12 can optionally include the reference levels being non-uniformly spaced across a range.

In Example 15, the residue-generating ADC of Example 12 or 14 can optionally include the reference levels being closer to each other near a center of a range than ends of the range.

In Example 16, the residue-generating ADC of any one of Examples 1-15 can optionally include the first continuous-time quantizer comprising continuous-time comparators.

In Example 17, the residue-generating ADC of any one of Examples 1-16 can optionally include first continuous-time quantizer not including switched-capacitor circuits.

In Example 18, the residue-generating ADC of any one of Examples 1-17 can optionally include the first continuous-time DAC and inputs to the first continuous-time DAC not being clocked or gated by clocks.

In Example 19, the residue-generating ADC of any one of Examples 1-18 can optionally include the first continuous-time DAC comprising current-mode DAC cells driven by respective outputs of the continuous-time quantizer.

In Example 20, the residue-generating ADC of any one of Examples 1-19 can optionally include the first continuous-time DAC comprising differential pairs of transistors and current sources.

In Example 21, the residue-generating ADC of Example 20 can optionally include the differential pairs of transistors being driven by respective differential outputs of continuous-time comparators.

In Example 22, the residue-generating ADC of any one of Examples 1-21 can optionally include the first filter comprises an amplifier to amplify the continuous-time summed signal.

Example 23 is a continuous-time residue-generating stage for an analog-to-digital converter (ADC), comprising: a delay circuit to delay an analog input signal; a quantizer to change an output responsive to the analog input signal crossing one of a plurality of reference levels; a digital-to-analog converter (DAC) responsive to the output of the quantizer; and a node to generate a summed signal based on a delayed analog input signal from the delay circuit and an output of the DAC.

In Example 24, the continuous-time residue-generating stage of Example 23 can optionally include a filter to filter the summed signal.

In Example 25, the continuous-time residue-generating stage of Example 22 or 23 can optionally include the delay circuit delaying the analog input signal by a same amount of latency of a signal path having the quantizer and the DAC.

In Example 26, the continuous-time residue-generating stage of any one of Examples 23-25 can optionally include the output of the quantizer changing aperiodically.

In Example 27, the continuous-time residue-generating stage of any one of Examples 23-26 can optionally include an output rate of the quantizer being adaptive to analog the input signal.

In Example 28, In Example 27, the continuous-time residue-generating stage of any one of Examples 23-27 can optionally include the reference levels being uniformly spaced across a range.

In Example 29, the continuous-time residue-generating stage of any one of Examples 23-27 can optionally include the reference levels being non-uniformly spaced across a range.

In Example 30, the continuous-time residue-generating stage of any one of Examples 23-29 can optionally include the output of the quantizer directly driving the DAC without being gated by a clock signal.

Example 31 is a method for preventing over-ranging of a residue signal in a residue-generating analog-to-digital converter (ADC), comprising: delaying an analog input signal; detecting the analog input signal crossing one of a plurality of reference levels; in response to detecting the crossing, changing a level-quantized signal; reconstructing the analog input signal based on the level-quantized signal; generating and amplifying the continuous-time residue signal based on a delayed analog input signal and a reconstructed analog input signal; and quantizing the continuous-time residue signal.

In Example 32, the method of Example 31 can optionally include: amplifying the continuous-time residue signal.

In Example 33, the method of Example 31 or 32 can optionally include changing the level-quantized signal comprising: changing the level-quantized signal-independent of a clock signal.

In Example 34, the method of any one of Examples 31-33 can optionally include reconstructing the analog input signal comprising reconstructing the analog input signal-independent of a clock signal.

In Example 35, the method of any one of Examples 31-34 can optionally include asynchronously filtering the level-quantized signal.

In Example 36, the method of any one of Examples 31-35 can optionally include sampling a continuous-time output of the residue-generating ADC.

Example 37 is an apparatus for implementing and/or carrying out any one of the methods described herein and Examples 31-36.

### Other Advantages, Considerations, Variations, and Implementations

By using event-driven, continuous-time, asynchronous feedforward path as illustrated in FIGS. 5, and 8-9, the aliasing and DAC image problem has been eliminated, and the residue is strictly bound to a smaller range. As a result, a primary cause for residue over-ranging has been removed. Implementing event-driven, continuous-time, asynchronous circuitry in the first stage of a residue-generating can be the most effective, since residue over-ranging problem is the most present in the first stage. Though, any other subsequent stage of the residue-generating ADC can also implement and benefit both of a strictly bound residue as well as an adaptive data rate.

When all stages of the residue-generating ADC is made of asynchronous circuitry, the reconstruction filter (reconstruction filter 530 and reconstruction filter 830) can also be implemented with asynchronous logic, hence making the design of the entire converter consistent and architecturally straightforward. The final output D_{OUT} can be digitally uniformly-sampled to be used by common clocked digital signal processing blocks.

Introducing the asynchronous, event-driven system in a first stage of a residue-generating ADC helps to mitigating yet another problem. Namely, the issue of the high frequency noise degradation of D₀ (and thus also D_{OUT}) due to sampling clock jitter. By using event-driven, asynchronous circuitry, the output of the DAC always changes by a single LSB per code transition (even though the output of the DAC may change more frequently than in the uniformly-sampled system). In contrast, the DAC output of a uniformly-sampled system output can change as much as the entire full output range from a sample to the next one, if V_{IN}'s frequency is fs/2 hence making it very sensitive to clock jitter. Also, when the DAC is event-driven, then the timing uncertainty in the DAC edge itself is smaller compared to the case when the DAC is triggered by clock CK. That also helps in reducing the sensitivity to the timing jitter.

Note that not all event-driven systems are clock-free and asynchronous in the sense of this disclosure. Some systems remove a synchronous master clock, but the stages are still (self-)clocked, which means that the operations in the stages are still triggered by a local clock signal or state machine. For instance, such systems still uses a synchronous clock signal to control operations of switched-capacitor circuits and/or sample-and-hold circuitry. In stark contrast, this disclosure describes purely clock-free residue-generating stage that can remove the issue of residue over-ranging all together. The clock-free residue-generating stages operate entirely without master or local clock generation, and are driven entirely by the input signal itself. The residue is thus created in continuous-time, using continuous-time circuitry.

For such (self-)clocked systems, the ADCs would still suffer from the residue over-ranging problem because the solution does not resolve the gap between the input that is still changing (continuous-time) and the quantized residue signal which has been time-sampled (or uniformly-sampled), and therefore has diverged from the input by the time the subtraction is performed. Even if, arguably, the (self-)clocked system may follow the input more closely, the system ultimately generates a residue signal that is quantize the input in time, responsive to a local clock. Therefore, the residue over-ranging problem is not entirely eliminated.

Most notably, in an event-driven, asynchronous, clock-free system, comparator detects an event, e.g., an input level-crossing, which then changes a level-quantized, continuous output. Accordingly, operation results in a signal quantization, which is quantized in voltage, not time. Subsequently, the comparator's continuous-time quantized output changes a DAC cell's output asynchronously, which in turn produces an analog voltage-domain quantized approximation (or reconstruction) of the analog input signal. This continuous-time quantized DAC output from the DAC cells is subtracted in continuous-time from the delayed analog input signal and therefore, creates a continuous-time residue signal. The continuous-time residue signal can be filtered through a continuous-time trans-impedance amplifier, which can implement low-pass filtering and amplification. The entire signal chain is absent of any master or local clocking system that triggers a sequence of phases to generate a residue signal.

Another strength of continuous-time analog circuits over clocked circuits is that continuous-time circuits avoids the power inefficiency associated with charging/discharging of switched-capacitor circuits. The overall circuit architecture and timing issues are simplified, because the generation of the residue signal occurs continuously, in real time, and not as a clocked charge-discharge-settle asynchronous timed system. The result is an architecture that avoids the settling error of a clocked system, which can cause serious non-linearity in the converter output.

A switch, used herein, refers to a transistor device operating as a switch, which can be turned on or off. When the switch is closed, the transistor device is biased to turn on (e.g., the transistor device is in a saturation region of operation). When the switch is closed, the transistor device is biased to turn off (e.g., the transistor device is in a cut-off region of operation). The state of the switch is controlled by a control signal. The control signal can be used to bias the transistor device to operate the transistor device in either the saturation region (“on” state) or in the cut-off region (“off” state).

In the discussions of the embodiments herein, the parts and components can readily be replaced, substituted, or otherwise modified in order to accommodate particular circuitry needs. Moreover, it should be noted that the use of complementary electronic devices, hardware, etc. offer an equally viable option for implementing the teachings of the present disclosure. For instance, complementary configurations using PMOS transistor(s) (p-type metal-oxide semiconductor transistor(s)) to replace NMOS transistor(s) (n-type metal-oxide semiconductor transistor(s)) or vice versa, are envisioned by the disclosure. For instance, the present disclosure encompasses implementations where all NMOS devices are replaced by PMOS devices, or vice versa. Connections and the circuit can be reconfigured to achieve the same function. These implementations are equivalent to the disclosed implementations using complementary transistors devices because the implementations would perform substantially the same function in substantially the same way to yield substantially the same result. It is understood by one skilled in the art that a transistor device can be generalized as a device having three terminals. Furthermore, it is understood by one skilled in the art that a switch, a transistor, or transistor device, during operation, can have a characteristic behavior of transistors corresponding to devices such as NMOS, PMOS devices (and any other equivalent transistor devices).

Note that the activities discussed above with reference to the FIGURES are applicable to any integrated circuits that involve processing analog signals and converting the analog signals into digital data using one or more ADCs. The features can be particularly beneficial to high speed ADCs, where input frequencies are relatively high in the Gigahertz range. The ADC can be applicable to medical systems, scientific instrumentation, wireless and wired communications systems (especially systems requiring a high sampling rate), radar, industrial process control, audio and video equipment, instrumentation, and other systems which uses ADCs. The level of performance offered by high speed ADCs can be particularly beneficial to products and systems in demanding markets such as high speed communications, medical imaging, synthetic aperture radar, digital beam-forming communication systems, broadband communication systems, high performance imaging, and advanced test/measurement systems (oscilloscopes).

The present disclosure encompasses apparatuses which can perform the various methods described herein. The apparatuses can include a suitable combination of means for implementing/carrying out any one of the methods described herein. Such apparatuses can include circuitry illustrated by the FIGURES and described herein. Parts of various apparatuses can include electronic circuitry to perform the functions described herein. The circuitry can operate in analog domain, digital domain, or in a mixed-signal domain.

It is also imperative to note that all of the specifications, dimensions, and relationships outlined herein have only been offered for purposes of example and teaching only. Such information may be varied considerably without departing from the spirit of the present disclosure, or the scope of the appended examples and claims described herein. The specifications apply only to one non-limiting example and, accordingly, they should be construed as such. In the foregoing description, example embodiments have been described with reference to particular component arrangements. Various modifications and changes may be made to such embodiments without departing from the scope of the appended examples and claims described herein. The description and drawings are, accordingly, to be regarded in an illustrative rather than in a restrictive sense.

Note that with the numerous examples provided herein, interaction may be described in terms of two, three, four, or more electrical components, or parts. However, this has been done for purposes of clarity and example only. It should be appreciated that the system can be consolidated in any suitable manner. Along similar design alternatives, any of the illustrated components, modules, blocks, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments. It is also important to note that the functions described herein illustrate only some of the possible functions that may be executed by, or within, systems/circuits illustrated in the FIGURES. Some of these operations may be deleted or removed where appropriate, or these operations may be modified or changed considerably without departing from the scope of the present disclosure. In addition, the timing of these operations may be altered considerably. The preceding operational flows have been offered for purposes of example and discussion. Substantial flexibility is provided by embodiments described herein in that any suitable arrangements, chronologies, configurations, and timing mechanisms may be provided without departing from the teachings of the present disclosure. Numerous other changes, substitutions, variations, alterations, and modifications may be ascertained to one skilled in the art and it is intended that the present disclosure encompass all such changes, substitutions, variations, alterations, and modifications as falling within the scope of the appended examples and claims described herein. Note that all optional features of the apparatus described above may also be implemented with respect to the method or process described herein and specifics in the examples may be used anywhere in one or more embodiments.

What is claimed is:

1. A residue-generating analog-to-digital converter (ADC), comprising:
a first residue-generating stage, comprising:
a first continuous-time delay circuit to receive an analog input signal and generate a delayed analog input signal;
a first continuous-time quantizer to receive the analog input signal and generate a continuous-time output signal;
a first continuous-time digital-to-analog converter (DAC) responsive to the continuous-time output signal;
a first summing node to receive the delayed analog input signal and an output from the first continuous-time DAC and generate a continuous-time summed signal; and
a first filter to filter the continuous-time summed signal, and generate a continuous-time residue signal; and
a second stage to quantize the continuous-time residue signal.

2. The residue-generating ADC of claim 1, further comprising:
a reconstruction filter to receive the continuous-time output signal from the first residue-generating stage and a further output signal from the second stage, and generate a final output of the residue-generating ADC.

3. The residue-generating ADC of claim 2, wherein the reconstruction filter comprises asynchronous logic.

4. The residue-generating ADC of claim 1, wherein the second stage comprises a second continuous-time delay circuit, a second continuous-time quantizer, a second continuous-time DAC, a second summing node, and a second filter.

5. The residue-generating ADC of claim 1, wherein the second stage comprises a second continuous-time quantizer.

6. The residue-generating ADC of claim 1, wherein the first continuous-time delay circuit comprises a resistor.

7. The residue-generating ADC of claim 1, wherein the first continuous-time delay circuit comprises a transmission line.

8. The residue-generating ADC of claim 1, wherein the first continuous-time delay circuit comprises a resistor-capacitor lattice.

9. The residue-generating ADC of claim 1, wherein the first continuous-time delay circuit comprises an inductor-capacitor lattice.

10. The residue-generating ADC of claim 1, wherein the first continuous-time quantizer is not triggered by any clock signals.

11. A continuous-time residue-generating stage for an analog-to-digital converter (ADC), comprising:
a delay circuit to delay an analog input signal;
a quantizer to change an output responsive to the analog input signal crossing one of a plurality of reference levels;
a digital-to-analog converter (DAC) responsive to the output of the quantizer; and
a node to generate a summed signal based on a delayed analog input signal from the delay circuit and an output of the DAC.

12. The continuous-time residue-generating stage of claim 11, further comprising:
a filter to filter the summed signal.

13. The continuous-time residue-generating stage of claim 11, wherein the delay circuit delays the analog input signal by a same amount of latency of a signal path having the quantizer and the DAC.

14. The continuous-time residue-generating stage of claim 11, wherein the output of the quantizer changes aperiodically.

15. The continuous-time residue-generating stage of claim 11, wherein an output rate of the quantizer is adaptive to the analog input signal.

16. The continuous-time residue-generating stage of claim 11, wherein the reference levels are uniformly spaced across a range.

17. The continuous-time residue-generating stage of claim 11, wherein the reference levels are non-uniformly spaced across a range.

18. The continuous-time residue-generating stage of claim 11, wherein the output of the quantizer directly drives the DAC without being gated by a clock signal.

19. A method for preventing over-ranging of a residue signal in a residue-generating analog-to-digital converter (ADC), comprising:
delaying an analog input signal;
detecting the analog input signal crossing one of a plurality of reference levels;
in response to detecting the crossing, changing a level-quantized signal;
reconstructing the analog input signal based on the level-quantized signal;
generating and amplifying the residue signal based on a delayed analog input signal and a reconstructed analog input signal; and
quantizing the residue signal.

20. The method of claim 19, further comprising:
amplifying the residue signal.
